(19) United States
(12) Patent Application Publication
(10) Pub. No.: US 2025/0342898 A1
(43) Pub. Date: Nov. 6, 2025

(54) ADAPTIVE BLOCK FAMILY ERROR AVOIDANCE IN A MEMORY SUB-SYSTEM

(71) Applicant: Micron Technology, Inc., Boise, ID (US)

(72) Inventors: Nicola Ciocchini, Boise, ID (US); Ugo Russo, Boise, ID (US); Thomas Herbert Lentz, Boise, ID (US); Steven Michael Kientz, Westminster, CO (US); Tomer Tzvi Eliash, Sunnyvale, CA (US); Chun Sum Yeung, San Jose, CA (US)

(21) Appl. No.: 19/174,050

(22) Filed: Apr. 9, 2025

Related U.S. Application Data
(60) Provisional application No. 63/642,064, filed on May 3, 2024.

(51) Int. Cl. G11C 29/52; G11C 16/26; G11C 16/34

(52) U.S. Cl. CPC G11C 29/52; G11C 16/26; G11C 16/3404

(57) ABSTRACT

A system includes a memory device and a processing device operatively coupled with the memory device to perform operations including receiving a read command specifying a logical address; translating the logical address into a physical address referencing a physical block stored on the memory device; identifying a wordline group associated with the physical address; identifying, based on block family metadata associated with the memory device, a block family associated with the physical block and the wordline group; determining a first threshold voltage offset associated with the block family; and reading, using the first threshold voltage offset, data from the physical block.

### REFERENCE TO RELATED APPLICATION

This application claims the priority benefit of U.S. Provisional Patent Application No. 63/642,064, filed May 3, 2024, the entirety of which is incorporated herein by reference.

### TECHNICAL FIELD

Embodiments of the disclosure relate generally to memory sub-systems, and, more specifically, relate to implementing adaptive block family error avoidance (BFEA) in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A illustrates an example computing system that includes a memory sub-system, in accordance with some embodiments of the present disclosure.

FIG. 1B is a block diagram of a memory device in communication with a memory sub-system controller of a memory sub-system, in accordance with some embodiments of the present disclosure.

FIGS. 2A-2C are diagrams of portions of an example array of memory cells included in a memory device, in accordance with some embodiments of the present disclosure.

FIGS. 3A-3B are diagrams of threshold voltage distributions illustrating an example implementation of adaptive block family error avoidance (BFEA) in a memory sub-system, in accordance with some embodiments of the present disclosure.

FIG. 4 is a simplified block diagram of a block table 410, a family table 420, and a wordline group offset table 430 in a memory sub-system, in accordance with some embodiments of the present disclosure.

FIG. 5 is a flow diagram of an example method to implement adaptive block family error avoidance (BFEA) in a memory sub-system, in accordance with some embodiments of the present disclosure.

FIG. 6 is a block diagram of an example computer system in which embodiments of the present disclosure may operate.

### DETAILED DESCRIPTION

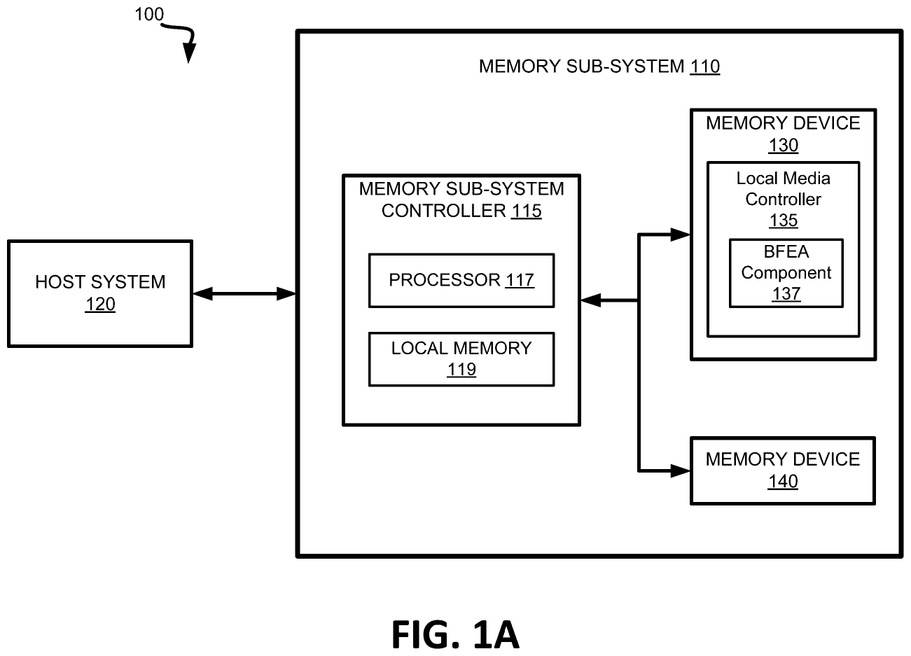

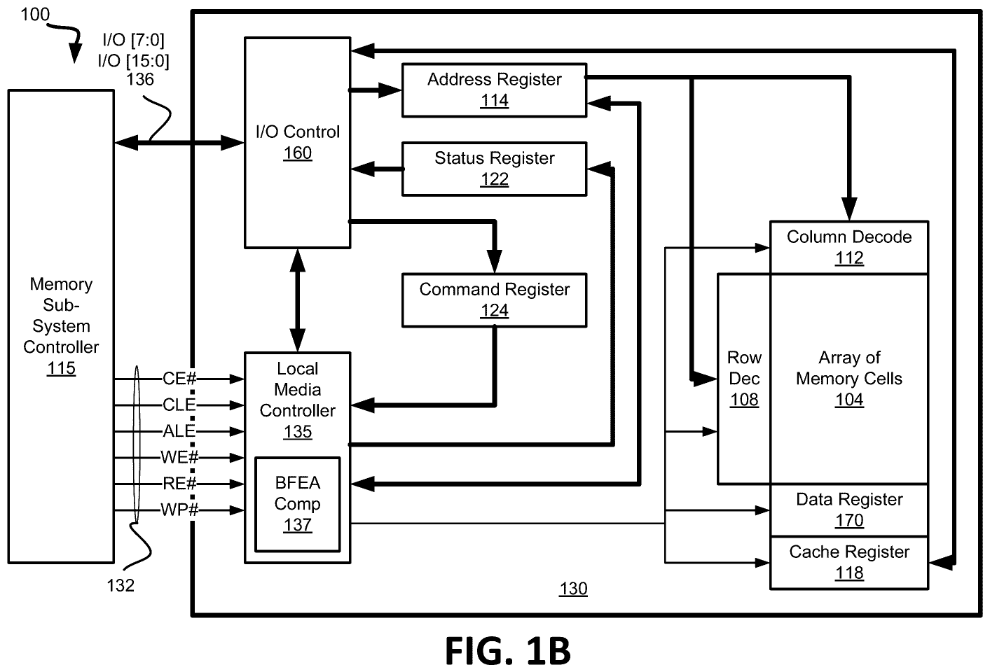

Aspects of the present disclosure are directed to implementing adaptive block family error avoidance (BFEA) in a memory sub-system. A memory sub-system can be a storage device, a memory module, or a combination of a storage device and a memory module. Examples of storage devices and memory modules are described below in conjunction with FIGS. 1A-1B. In general, a host system can utilize a memory sub-system that includes one or more components, such as memory devices that store data. The host system can provide data to be stored at the memory sub-system and can request data to be retrieved from the memory sub-system.

A memory sub-system can include high-density non-volatile memory devices where retention of data is desired when no power is supplied to the memory device. One example of a non-volatile memory device is a negative-AND (NAND) memory device. Other examples of non-volatile memory devices are described below in conjunction with FIGS. 1A-1B. A non-volatile memory device is a package of one or more dies. Each die includes one or more planes. For some types of non-volatile memory devices (e.g., NAND devices), each plane includes a set of physical blocks. Each block consists of a set of pages. Each page includes a set of memory cells. A memory cell is an electronic circuit that stores information. Depending on the memory cell type, a memory cell can store one or more bits of binary information and has various logic states that correlate to the number of bits being stored. The logic states can be represented by binary values, such as “0” and “1”, or combinations of such values.

A memory device can include multiple memory cells arranged in a two-dimensional or three-dimensional grid. Memory cells are formed onto a silicon wafer in an array of columns and rows. A memory device can further include conductive lines connected to respective ones of the memory cells, referred to as wordlines and bitlines. A wordline can be connected to one or more rows of memory cells of the memory device and a bitline can be connected to one or more columns of memory cells. The intersection of a bitline and wordline constitutes the address of the memory cell. One or more wordlines can be grouped together in a wordline group. Each wordline group can include a predetermined number (K) of adjacent wordlines. For example, a first wordline group can include wordlines 1 through K, a second wordline group can include wordlines (K+1) to 2K, a third wordline group can include wordlines (2K+1) to 3K, etc. A block hereinafter refers to a unit of the memory device used to store data and can include a group of memory cells connected to a certain subset of wordlines of the memory device. One or more blocks can be grouped together to form a plane of the memory device in order to allow concurrent operations to take place on each plane. The memory device can include circuitry that performs concurrent memory page accesses of two or more memory planes. For example, the memory device can include a respective access line driver circuit and power circuit for each plane of the memory device to facilitate concurrent access of pages of two or more memory planes, including different page types.

Some memory devices can be three-dimensional (3D) memory devices (e.g., 3D NAND devices). For example, a 3D memory device can include memory cells that are placed between sets of layers including a pillar (e.g., polysilicon pillar), a tunnel oxide layer, a charge trap (CT) layer, and a dielectric (e.g., oxide) layer. For example, a 3D memory device can be a 3D replacement gate memory device having a replacement gate structure using wordline stacking.

A memory cell (“cell”) can be programmed (e.g., written to) by applying a certain voltage to the cell, which results in an electric charge being held by the cell. For example, a voltage signal V_{CG} can be applied to a control electrode of the cell to open the cell to the flow of electric current across the cell between a source electrode and a drain electrode. More specifically, for each individual cell (having a charge Q stored thereon), there can be a threshold control gate voltage V_{T} (also referred to as the “threshold voltage”) such that the source-drain electric current is low for the control gate voltage (V_{CG}) being below the threshold voltage, V_{CG}<V_{T}. The current increases substantially once the control gate voltage has exceeded the threshold voltage, V_{CG}>V_{T}. Because the actual geometry of the electrodes and gates varies from cell to cell, the threshold voltages can be different even for cells implemented on the same die. The cells can, therefore, be characterized by a distribution P of the threshold voltages, P(Q, V_{T})=dW/dV_{T}, where dW represents the probability that any given cell has its threshold voltage within the interval [V_{T}, V_{T}+dV_{T}] when charge Q is placed on the cell.

A memory device can exhibit threshold voltage distributions P(Q, V_{T}) that are narrow compared with the working range of control voltages tolerated by the cells of the device. Accordingly, multiple non-overlapping distributions P (Qₖ, V_{T}) (“valleys”) can be fit into the working range, allowing for storage and reliable detection of multiple values of the charge Qₖ, k=1, 2, 3. . . The distributions (valleys) are interspersed with voltage intervals (“valley margins”) where none (or very few) of the cells of the device have their threshold voltages. Such valley margins can, therefore, be used to separate various charge states Qₖ. The logical state of the cell can be determined by detecting, during a read operation, between which two valley margins the respective threshold voltage V_{T} of the cell resides. Specifically, the read operation can be performed by comparing the measured threshold voltage V_{T} exhibited by the memory cell to one or more reference voltage levels corresponding to known valley margins (e.g., centers of the margins) of the memory device.

One type of cell is a single level cell (SLC), which stores 1 bit per cell and defines 2 logical states (“states”) (“1” or “L0” and “0” or “L1”), each corresponding to a respective VT level. For example, the “1” state can be an erased state (L0), and the “0” state can be a programmed state (L1). Another type of cell is a multi-level cell (MLC), which stores 2 bits per cell and defines 4 states (“11” or “L0”, “10” or “L1”, “01” or “L2” and “00” or “L3”), each corresponding to a respective V_{T} level. For example, the “11” state can be an erased state, and the “01”, “10” and “00” states can each be a respective programmed state. Another type of cell is a triple level cell (TLC), which stores 3 bits per cell and defines 8 states (“111” or “L0”, “110” or “L1”, “101” or “L2”, “100” or “L3”, “011” or “L4”, “010” or “L5”, “001” or “L6”, and “000” or “L7”), each corresponding to a respective V_{T} level. For example, the “111” state can be an erased state, and each of the other states can be a respective programmed state. Another type of a cell is a quad-level cell (QLC), which stores 4 bits per cell and defines 16 states L0-L15, where LO corresponds to “1111” and L15 corresponds to “0000”. Another type of cell is a penta-level cell (PLC), which stores 5 bits per cell and defines 32 states. Other types of cells are also contemplated. A memory device can include one or more arrays of memory cells such as SLCs, MLCs, TLCs, QLCs, PLCs, etc., or any combination of such. For example, a memory device can include an SLC portion, an MLC portion, a TLC portion, a QLC portion, or a PLC portion of cells.

A valley margin can also be referred to as a read window. For example, in an SLC cell, there is 1 read window that exists with respect to the 2 V_{T} distributions. As another example, in an MLC cell, there are 3 read windows that exist with respect to the 4 V_{T} distributions. As yet another example, in a TLC cell, there are 7 read windows that exist with respect to the 8 V_{T} distributions. Read window size generally decreases as the number of states increases. For example, the 1 read window for the SLC cell may be larger than each of the 3 read windows for the MLC cell, and each of the 3 read windows for the MLC cell may be larger than each of the 7 read windows for the TLC cell, etc. Read window budget (RWB) refers to the cumulative value of the read windows.

As data is repeatedly written and erased in a memory device, such as a flash memory, the memory device may be more susceptible to errors due to various types of noise and disturb mechanisms inherent within the memory cell, which may be exacerbated with repeated programming. As a result, the raw bit error rates (RBERs) for the memory device can increase over time. Given this pattern, the end-of-life RBERs for these devices are much higher as compared to the beginning-of-life RBERs for the respective devices.

To address read errors, a memory sub-system can use an error handling technique to correct errors and verify that the data written into the memory device is the same as the data being read from the respective memory device. In some embodiments, the error handling technique can include performing one or more read retries using different parameters, such as a change in the threshold voltage offset as compared to the initial threshold voltage offset applied in performing a read operation on a set of memory cells.

One phenomenon observed in memory devices is slow charge loss (SCL), which can occur as a function of elapsed time since programming and/or temperature. Charge loss can cause a V_{T} distribution shift, in which V_{T} distributions shift towards lower voltage levels. That is, the V_{T} distribution shift can be proportional to the elapsed time from a programming operation to a read operation and/or temperature. Charge loss and the corresponding V_{T} distribution shift can, over time, lead to increasing bit error rates (e.g., raw bit error rates (RBERs)) that require increasing amounts of error correction to address, and, accordingly, increasing amounts of system resources.

Depending on the system workload and program-erase cycles, the elapsed times since programming may vary across blocks. These variations in the elapsed time since programming can result in varying, non-uniform V_{T} distribution shifts of respective blocks if the programming of blocks is spaced significantly in time. As a result of these non-uniform VT distribution shifts, it can be difficult to predict an optimal threshold voltage offset that needs to be applied to the majority of the blocks across wordlines to address charge loss without compromising performance.

In some implementations, the charge loss can be tracked by implementing the block family error avoidance (BFEA), which involves assigning each block of a memory device to a respective predefined block family (BF). Each BF can define a grouping of blocks having a substantially similar elapsed time since programming (e.g., are programmed at or around the same time). Each BF can be assigned to a respective threshold voltage offset bin (“bin”), where each BFEA bin includes a set of threshold level offsets to be applied to respective programming voltage levels to account for VT distribution shifts over time resulting from the slow charge loss. As mentioned above, the amount of charge loss of a block can be a function of the elapsed time from a programming operation and/or temperature. Each BFEA bin can be assigned a respective bin index representing a bin number.

When a block is initially programmed at time 0, the block can be initially assigned to the currently open BF, where the currently open BF is associated with a first bin (e.g., bin 1). A media scan operation can be performed on representative blocks of each BF at a particular respective V_{T} level periodically (e.g., every few hours) to determine whether the threshold voltage offset for a block, and thus the BFEA bin assignment, should be updated to better track V_{T} distribution shift over time. For example, if the media scan operation indicates that the threshold voltage offset should be updated to the threshold voltage offset assigned to a second bin (e.g., bin 2), then the block can be reassigned to the second bin.

As discussed above, variations in the elapsed time since programming across blocks can result in varying, non-uniform V_{T} distribution shifts of respective blocks. As such, applying a single threshold voltage offset to each block assigned to a respective BFEA bin may not compensate for any wordline group to wordline group variations in the memory device. More specifically, blocks included in a certain wordline group may experience varying, non-uniform V_{T} distribution shifts in comparison to blocks included in another wordline group.

Aspects of the present disclosure address the above and other deficiencies by assigning each wordline group of a given block to a corresponding block family (rather than assigning a whole block to the block family), thus taking into account wordline-to-wordline variations in V_{T} distribution shifts across the different wordline groups.

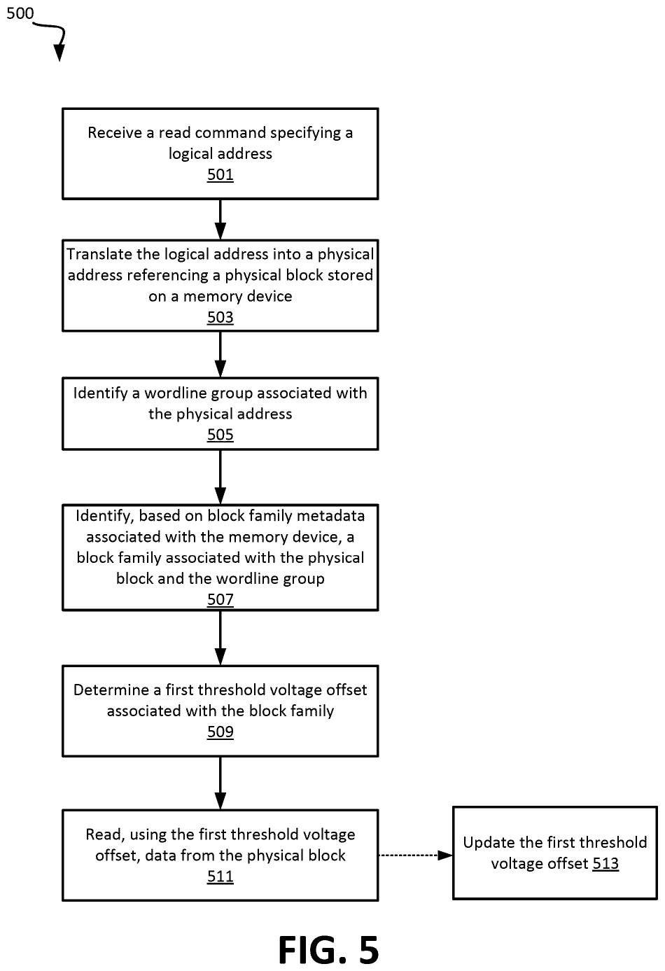

The threshold voltage offset corresponding to a particular wordline group can then be applied when performing nonsequential read operations on sets of memory cells addressable by wordlines of the particular wordline group. In some implementations, the threshold voltage offset assigned to a particular bin can be updated in response to detecting a read error when performing a read operation on a set of memory cells addressable by a wordline of a particular wordline group. In response to detecting the read error, an error handling operation can be performed on the set of memory cells to successfully recover data stored in the set of memory cells. The memory sub-system controller can then update the particular BFEA bin with the threshold voltage offset identified by the error handling operation, as described in further detail herein with respect to FIG. 5. Accordingly, updated threshold voltage offsets can be determined and then stored, even during a non-sequential read operation, for use in performing subsequent read operations on memory cells assigned to a particular BFEA bin. Further, using the updated threshold voltage offsets can also account for the variations of V_{T} distribution shifts across wordline groups and for the read errors due to charge loss and the corresponding VT distribution shift at different V_{T} levels.

Advantages of the present disclosure include improved memory device performance and reliability. For example, embodiments described herein can achieve improved performance consistency across SCL conditions. Accordingly, embodiments described herein can be implemented to reduce read errors and increase the life of a memory device.

The method can be implemented with any suitable memory device architecture in accordance with the embodiments described herein. In one embodiment, the method can be implemented with a memory device implementing replacement gate NAND (RG NAND) technology. A replacement gate (RG) NAND device is a NAND device that implements a RG architecture rather than a floating gate (FG) architecture. The RG NAND architecture removes cell gaps that are typically found in FG NAND architectures, thereby reducing or eliminating capacitance resulting from those cell gaps. More specifically, the RG NAND architecture corresponds to a single-insulator structure. The RG NAND architecture can enable smaller size, improved read and write latency, and an increase in transfer rate as compared to the FG NAND architecture. Further details regarding implementing adaptive block family error avoidance (BFEA) in a memory sub-system will be described below with reference to FIGS. 1A-6.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Pillar, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-AND (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single-level memory cells (SLC), can store one bit per memory cell. Other types of memory cells, such as multi-level memory cells (MLCs), triple-level memory cells (TLCs), quad-level memory cells (QLCs), and penta-level memory cells (PLCs) can store multiple bits per memory cell. In some embodiments, each of the memory devices 130 can include one or more arrays of memory cells such as SLCs, MLCs, TLCs, QLCs, PLCs, or any combination of such. In some embodiments, a particular memory device can include an SLC portion, an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application-specific integrated circuit (ASIC), etc.), or another suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control the operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local controller 132) on the die and a controller (e.g., memory sub-system controller 115) for media management within the same memory device package. An example of a managed memory device is a managed NAND (MNAND) device.

The local media controller 135 can implement a block family error avoidance (BFEA) component 137. The BFEA component 137 can receive a set of bins. The set of bins can be predefined and stored on the local media controller 135. Each bin of the set of bins corresponds to a grouping of blocks of the memory device 130. Each bin of the set of bins is assigned to a respective set of threshold voltage offsets (e.g., for read levels 0 to 7, as discussed above).

The local media controller 135 can maintain a set of bins. Each block family of the memory device is assigned to a respective bin based on elapsed time since programming of the block. Moreover, each bin of the set of bins can be associated with a respective set of threshold voltage offsets that can be used to read the blocks assigned to the bin. Maintaining the set of bins can include updating the set of bins, as described in further detail with respect to FIG. 5.

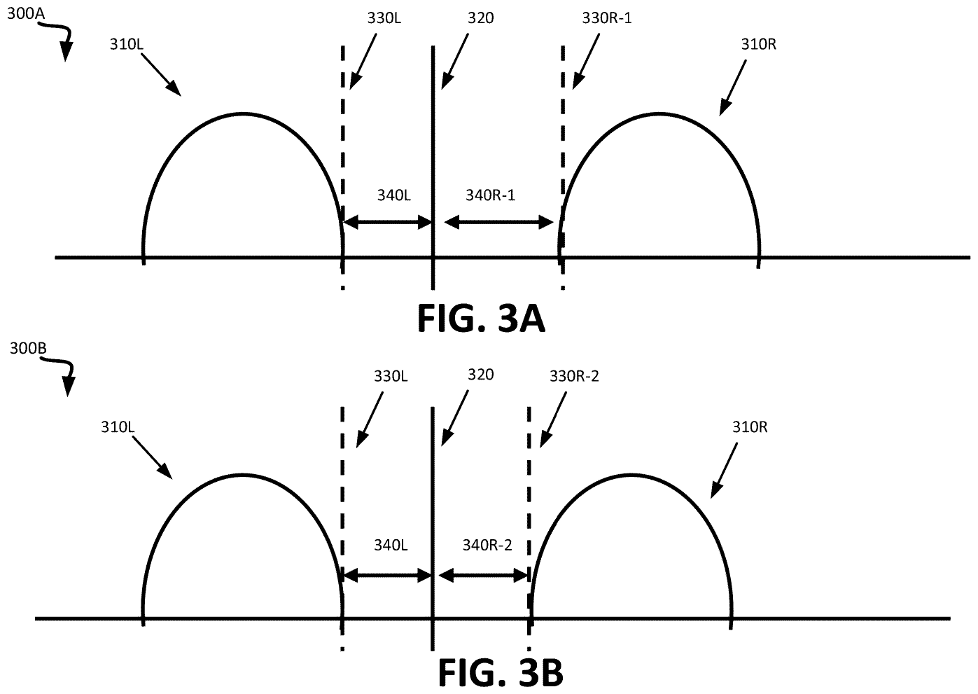

The local media controller can receive a read command specifying a logical address. For example, the read command can be received from the host system 120 via the memory sub-system controller 115. Upon receiving the request, the BFEA component 137 can translate the logical address into a physical address, where the physical address references a physical block stored on the memory device. The BFEA component 137 can then identify a wordline group associated with the physical address. The BFEA component 137 can then identify (e.g., based on block family metadata) a block family that included the physical block and the wordline group. The BFEA component 137 can determine a first threshold voltage offset for the block family. More specifically, the BFEA component 137 can identify the bin of the set of bins to which the block family is assigned to and select a threshold voltage offset assigned to the block family for the wordline group. The BFEA component 137 can read, using the threshold voltage offset, data from the physical block. Further details regarding the operations of the BFEA component 137 will be described below with reference to FIGS. 3A-5.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device.

Memory device 130 includes an array of memory cells 104 logically arranged in rows and columns. Memory cells of a logical row are connected to the same access line (e.g., a wordline) while memory cells of a logical column are selectively connected to the same data line (e.g., a bitline). A single access line may be associated with more than one logical row of memory cells and a single data line may be associated with more than one logical column. Memory cells (not shown in FIG. 1B) of at least a portion of an array of memory cells 104 are capable of being programmed to one of at least two target data states.

Row decode circuitry 108 and column decode circuitry 112 are provided to decode address signals. Address signals are received and decoded to access the array of memory cells 104. Memory device 130 also includes input/output (I/O) control circuitry 160 to manage input of commands, addresses, and data to the memory device 130 as well as output of data and status information from the memory device 130. An address register 114 is in communication with I/O control circuitry 160 and row decode circuitry 108 and column decode circuitry 112 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 112 to control the row decode circuitry 108 and column decode circuitry 112 in response to the addresses. In one embodiment, local media controller 135 includes the BFEA component 137.

The local media controller 135 is also in communication with a cache register 118. Cache register 118 latches data, either incoming or outgoing, as directed by the local media controller 135 to temporarily store data while the array of memory cells 104 is busy writing or reading, respectively, other data. During a program operation (e.g., write operation), data may be passed from the cache register 118 to the data register 170 for transfer to the array of memory cells 104; then new data may be latched in the cache register 118 from the I/O control circuitry 160. During a read operation, data may be passed from the cache register 118 to the I/O control circuitry 160 for output to the memory sub-system controller 115; then new data may be passed from the data register 170 to the cache register 118. The cache register 118 and/or the data register 170 may form (e.g., may form a portion of) a page buffer of the memory device 130. A page buffer may further include sensing devices (not shown in FIG. 1B) to sense a data state of a memory cell of the array of memory cells 204, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) may be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 136 and outputs data to the memory sub-system controller 115 over I/O bus 136.

For example, the commands may be received over input/output (I/O) pins [7:0] of I/O bus 136 at I/O control circuitry 160 and may then be written into command register 124. The addresses may be received over input/output (I/O) pins [7:0] of I/O bus 136 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 118. The data may be subsequently written into data register 170 for programming the array of memory cells 104.

In an embodiment, cache register 118 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIGS. 1A-1B has been simplified. It should be recognized that the functionality of the various block components described with reference to FIGS. 1A-1B may not necessarily be segregated to distinct components or component portions of an integrated circuit device. For example, a single component or component portion of an integrated circuit device could be adapted to perform the functionality of more than one block component of FIGS. 1A-1B. Alternatively, one or more components or component portions of an integrated circuit device could be combined to perform the functionality of a single block component of FIGS. 1A-1B. Additionally, while specific I/O pins are described in accordance with popular conventions for receipt and output of the various signals, it is noted that other combinations or numbers of I/O pins (or other I/O node structures) may be used in the various embodiments.

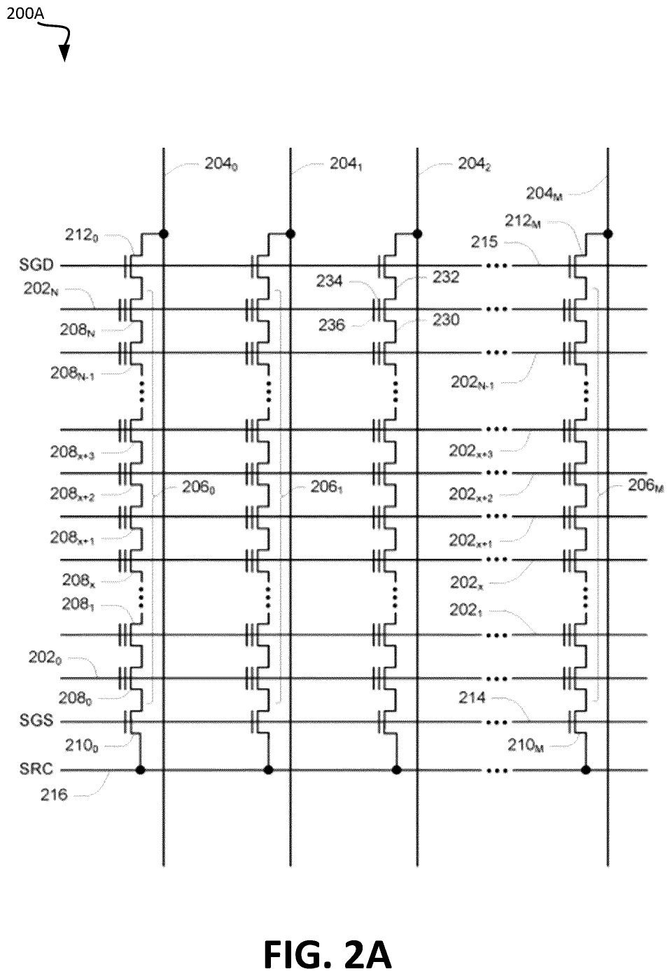

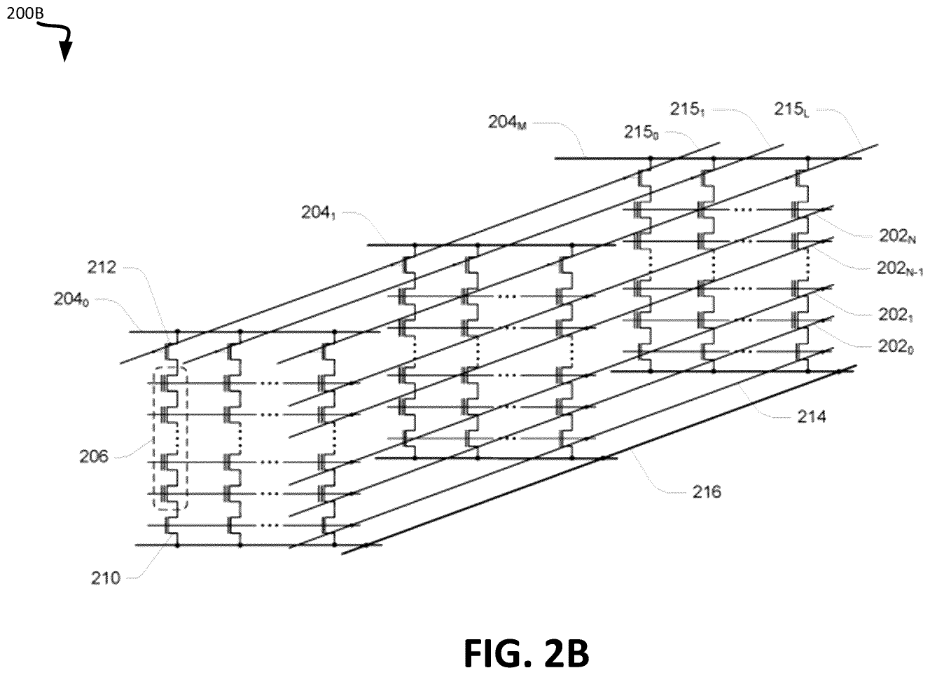

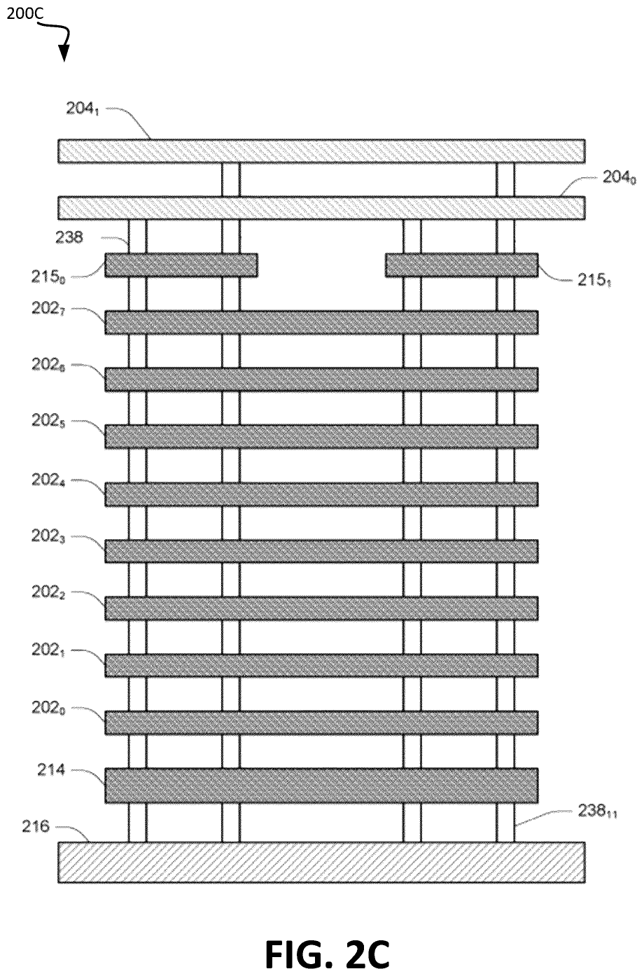

FIGS. 2A-2C are diagrams of portions of an example array of memory cells included in a memory device, in accordance with some embodiments of the present disclosure. For example, FIG. 2A is a schematic of a portion of an array of memory cells 200A as could be used in a memory device (e.g., as a portion of array of memory cells 104). Memory array 200A includes access lines, such as wordlines 202₀ to 202_{N}, and a data line, such as bitline 204. The wordlines 202 may be connected to global access lines (e.g., global wordlines), not shown in FIG. 2A, in a many-to-one relationship. For some embodiments, memory array 200A may be formed over a semiconductor that, for example, may be conductively doped to have a conductivity type, such as a p-type conductivity, e.g., to form a p-well, or an n-type conductivity, e.g., to form an n-well.

Memory array 200A can be arranged in rows, each corresponding to a respective wordline 202, and columns, each corresponding to a respective bitline 204. Rows of memory cells 208 can be divided into one or more groups of physical pages of memory cells 208, and physical pages of memory cells 208 can include every other memory cell 208 commonly addressable by a given wordline 202. For example, memory cells 208 commonly addressable by wordline 202_{N} and selectively connected to even bitlines 204 (e.g., bitlines 204₀, 204₂, 204₄, etc.) may be one physical page of memory cells 208 (e.g., even memory cells) while memory cells 208 commonly addressable by wordline 202_{N} and selectively connected to odd bitlines 204 (e.g., bitlines 204₁, 204₃, 204₅, etc.) may be another physical page of memory cells 208 (e.g., odd memory cells). Although bitlines 204₃-204₅ are not explicitly depicted in FIG. 2A, it is apparent from the figure that the bitlines 204 of the array of memory cells 200A may be numbered consecutively from bitline 204₀ to bitline 204_{M}. Other groupings of memory cells 208 commonly addressable by a given wordline 202 may also define a physical page of memory cells 208. For certain memory devices, all memory cells commonly addressable by a given wordline may be deemed a physical page of memory cells. The portion of a physical page of memory cells (which, in some embodiments, could still be the entire row) that is read during a single read operation or programmed during a single programming operation (e.g., an upper or lower page of memory cells) may be deemed a logical page of memory cells. A block of memory cells may include those memory cells that are configured to be erased together, such as all memory cells addressable by wordlines 202₀-202_{N} (e.g., all strings 206 sharing common wordlines 202). A reference to a page of memory cells herein can refer to the memory cells of a logical page of memory cells.

Each column can include a string of series-connected memory cells (e.g., non-volatile memory cells), such as one of strings 206₀ to 206_{M}. Each string 206 can be connected (e.g., selectively connected) to a source line 216 (SRC) and can include memory cells 208₀ to 208_{N}. The memory cells 208 of each string 206 can be connected in series between a select gate 210, such as one of the select gates 210₀ to 210_{M}, and a select gate 212, such as one of the select gates 212₀ to 212_{M}. In some embodiments, the select gates 210₀ to 210_{M} are source-side select gates (SGS) and the select gates 212₀ to 212_{M} are drain-side select gates. Select gates 210₀ to 210_{M} can be connected to a select line 214 (e.g., source-side select line) and select gates 212₀ to 212_{M} can be connected to a select line 215 (e.g., drain-side select line). The select gates 210 and 212 may represent a plurality of select gates connected in series, with each select gate in series configured to receive a same or independent control signal. A source of each select gate 210 can be connected to SRC 216, and a drain of each select gate 210 can be connected to a memory cell 208₀ of the corresponding string 206. Therefore, each select gate 210 can be configured to selectively connect a corresponding string 206 to SRC 216. A control gate of each select gate 210 can be connected to select line 214. The drain of each select gate 212 can be connected to the bitline 204 for the corresponding string 206. The source of each select gate 212 can be connected to a memory cell 208_{N} of the corresponding string 206. Therefore, each select gate 212 may be configured to selectively connect a corresponding string 206 to the bitline 204. A control gate of each select gate 212 can be connected to select line 215.

In some embodiments, and as will be described in further detail below with reference to FIG. 2B, the memory array in FIG. 2A is a three-dimensional memory array, in which the strings 206 extend substantially perpendicular to a plane containing SRC 216 and to a plane containing a plurality of bitlines 204 that can be substantially parallel to the plane containing SRC 216.

FIG. 2B is another schematic of a portion of an array of memory cells 200B (e.g., a portion of the array of memory cells 104) arranged in a three-dimensional memory array structure. The three-dimensional memory array 200B may incorporate vertical structures which may include semiconductor pillars where a portion of a pillar may act as a channel region of the memory cells of strings 206. The strings 206 may be each selectively connected to a bit line 204₀-204_{M} by a select gate 212 and to the SRC 216 by a select gate 210. Multiple strings 206 can be selectively connected to the same bitline 204. Groups of strings 206 can be connected to their respective bitlines 204 by biasing the select lines 215₀-215_{L} to selectively activate particular select gates 212 each between a string 206 and a bitline 204. The select gates 210 can be activated by biasing the select line 214. Each wordline 202 may be connected to multiple rows of memory cells of the memory array 200B. Rows of memory cells that are commonly addressable by each other by a particular wordline 202 may collectively be referred to as tiers.

FIG. 2C is a diagram of a portion of an array of memory cells 200C (e.g., a portion of the array of memory cells 104). Channel regions (e.g., semiconductor pillars) 238 represent the channel regions of different strings of series-connected memory cells (e.g., strings 206 of FIGS. 2A-2B) selectively connected to the bitline 204₀ and/or bitline 2041. A memory cell (not depicted in FIG. 2C) may be formed at each intersection of a wordline 202 and a channel region 238, and the memory cells corresponding to a single channel region 238 may collectively form a string of series-connected memory cells (e.g., a string 206 of FIGS. 2A-2B). Additional features may be common in such structures, such as dummy wordlines, segmented channel regions with interposed conductive regions, etc.

FIGS. 3A-3B are diagrams of V_{T} distributions illustrating an example implementation of adaptive block family error avoidance (BFEA) in a memory sub-system, in accordance with some embodiments of the present disclosure. For example, FIG. 3A illustrates a diagram 300A of a left V_{T} distribution 310L and a right V_{T} distribution 310R at a first time. For example, the first time can be the time of programming (e.g., time 0). A center read level 320 can exist in the valley between the V_{T} distributions 310L and 310R. The valley defines a read window. A boundary 330 L can be identified for the left V_{T} distribution 310L and a boundary 330R-1 can be identified for the right V_{T} distribution 310R. The distance between the center read level 320 and the boundary 330L defines a left portion of the read window 340L. The boundaries 340L-1 and 340R-1 can each be identified from a threshold bit error rate (e.g., RBER). The boundaries 340L-1 and 340R-1 can be identified empirically by analyzing charge loss after memory device manufacture. A distance between the center read level 320 and the boundary 340R-1 defines a right portion of the read window 340R-1.

FIG. 3B illustrates a diagram 300B of the left V_{T} distribution 310L and the right V_{T} distribution 310R at a second time after the first time. Due to charge loss that occurred between the first time and the second time, at least the right V_{T} distribution 310R shifted to the left. If the boundary 330R-1 from FIG. 3A remains at the same position, this would result in a bit error rate that exceeds the threshold bit error rate. Thus, to address the shift of the right V_{T} distribution 310R caused by the charge loss, the boundary 330R-1 is updated to boundary 330R-2, which results in an updated distance between the center read level 320 and the boundary 330R-2 defining a right portion of the read window 340R-2. The updated distance is smaller than the previous distance, and thus the right portion of the read window 340R-2 is smaller than the right portion of the read window 340R-1. Moreover, the read window itself has been reduced due to the shift of the right V_{T} distribution 310R.

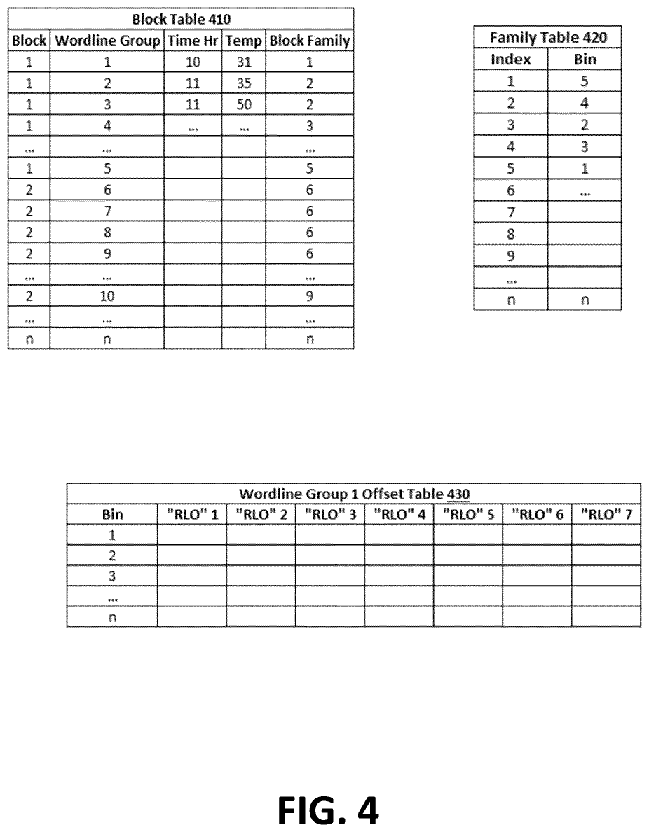

FIG. 4 is a simplified block diagram of a set of data structures, including a block table 410, a family table 420, and a wordline group “1” offset table 430 in a memory sub-system, in accordance with some embodiments of the present disclosure.

Each of the block table 410, the family table 420, and the wordline group “1” offset table 430 can be stored in the memory device 130 of FIG. 1A. In this example, each table can be a lookup table accessible by a memory sub-system controller to identify a particular BFEA bin mapped to a particular wordline group.

Each record of the block table 410 specifies the block family and wordline group associated with a specified block. In some implementations, the block table records can further include time and temperature values associated with the specified block and wordline group combination. Wordlines can be grouped together in a wordline group based on a position of a wordline in relation to other wordlines of the block. Wordlines that are in physical proximity to one another (e.g., are adjacent to one another) can be grouped together in a particular wordline group. In some embodiments, the maximum amount of wordlines that can be grouped together in a particular wordline group can be predefined, e.g., during the manufacturing and/or design of the memory device using offline testing and experimental data.

The family table 420 is indexed by the block family number, such that each record of the family table 420 specifies, for the block family referenced by the index of the record, a set of threshold voltage offset bins (e.g., BFEA bins) associated with the block family.

Finally, there can be a set of wordline group offset tables, where each wordline group offset table maps a particular set of threshold voltage offsets to a particular BFEA bin for a particular wordline group. For example, the wordline group 1 offset table 430 can map, for wordline group 1, a particular set of threshold voltage offsets to a particular BFEA bin. Specifically, the wordline group 1 offset table 330 is indexed by the bin number. Each record of the offset table 430 specifies a set of threshold voltage offsets (e.g., read levels 0 to 7, as discussed above) associated with a particular BFEA bin. There can be a wordline group offset table for each wordline group (e.g., wordline group 1 to wordline group n).

In some embodiments, the memory sub-system controller can identify for each BFEA bin associated with a particular block family, using the block table 410 and/or another data structure in the memory sub-system, an associated temperature value and/or a read level offset modification computation. In some embodiments, the temperature value is a read temperature value measured at a time when a request is received to perform a read operation at a set of memory cells included in a block. In some embodiments, the temperature value can be a temperature value measured at a time when a block family is created. In some embodiments, the temperature value can be measured using a temperature sensor (e.g., an on-die temperature sensor) of the memory device 130. In some embodiments, the temperature sensor can be located elsewhere in the memory sub-system 110. In some embodiments, a read level offset modification computation defines a computation to be performed to modify a threshold voltage offset for a particular BFEA bin. In some embodiments, the read level offset modification computation can be initialized during manufacturing and/or design of the memory device using offline testing and experimental data.

In some embodiments, a memory sub-system controller can update a threshold voltage offset assigned to a particular BFEA bin, as discussed further with regard to FIG. 5. In some embodiments, using the wordline group 1 offset table 430 as an example, to update the threshold voltage offset assigned to a particular BFEA bin for wordline group 1, the memory sub-system controller can identify an entry of the offset table 430 that includes an identifier of the particular BFEA bin. For example, for programming operations performed on memory cells that are along wordline group 1 mapped to bin “1” (where the bin can be identified using the family table 420 described with reference to FIG. 4), the memory sub-system controller can identify the entry bin “1” in the offset table 430. The memory sub-system controller can identify that, in the corresponding row for bin “1,” bin “1” is mapped to a set of threshold voltage offsets. In some embodiments, the memory sub-system controller can update a threshold voltage offset by replacing the threshold voltage offset with an updated threshold voltage offset. In some embodiments, the memory sub-system controller can determine the updated threshold voltage offset by performing a modification to the threshold voltage offset, as discussed further with regard to FIG. 5.

FIG. 5 is a flow diagram of an example method 500 to implement adaptive block family error avoidance (BFEA) in a memory sub-system, in accordance with some embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by the BFEA component 137 of FIG. 1A. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 501, the processing logic receives a read command specifying a logical address on which to perform a read operation. In some embodiments, the processing logic can receive the read command from a host system (e.g., the host system 120 of FIG. 1A).

At operation 503, in response to receiving the read command, the processing logic can translate the logical address specified by the read command into a physical address referencing a physical block stored on the memory device (e.g., the memory device 130 of FIG. 1A). For example, the processing logic can translate the logical address into the physical address using a logical-to-physical (L2P) address mapping data structure. In some implementations, the L2P address mapping data structure can be stored on the memory device, and each entry of the L2P address mapping data structure can include a logical address and a corresponding physical address.

At operation 505, the processing logic can identify a wordline group associated with the physical address. For example, using components of the physical address, such as the physical block number, the processing logic can use the block table 410 of FIG. 4 to identify the wordline group corresponding to the physical block number.

At operation 507, the processing logic can identify a block family associated with the physical block and the wordline group identified at operation 505. For example, the processing logic can use block family metadata (e.g., the block table 410 of FIG. 4) to identify the block family.

At operation 509, the processing logic can determine a first threshold voltage offset associated with the block family identified at operation 507. For example, the processing logic can use the block family identifier as an index to identify, using the family table 420, the bin assigned to the block family. Then, the processing logic can use the wordline group identifier (e.g., wordline group 1) and the identified bin assigned to the block family as an index to identify, using the offset table 430, a first threshold voltage offset of a set of threshold voltage offsets.

At operation 511, in response to identifying the set of threshold voltage offsets assigned to the identified bin for the particular wordline group at operation 509, the processing logic can read data from the physical block using the first threshold voltage offset of the set of threshold voltage offsets.

In some embodiments, at operation 513, the processing logic can update the first threshold voltage offset in response to detecting a read error in response to reading the data from the physical block using the first threshold voltage offset. For example, the processing logic can perform an error handling operation on the set of memory cells addressable by the wordline group. “Read error” refers to a memory sub-system's failure to validate one or more data items that have been retrieved from a memory device in response to a read command. For example, read errors can occur due to, for example, the measured threshold voltage V_{T} exhibited by the set of memory cells mismatching the threshold voltage levels due to SCL, as discussed above. In some embodiments, the error handling operation can include performing one or more read retries using different parameters, such as a change in the threshold voltage offset as compared to the initial threshold voltage offset applied in performing the read operation on the set of memory cells. The processing logic identifies the threshold voltage offset that lead to successfully recovering data stored in the set of memory cells.

In response to identifying the threshold voltage offset that lead to successfully recovering the data stored in the set of memory cells, the processing logic can update, in the entry of the offset table 430, the first threshold voltage offset with the threshold voltage offset that lead to successfully recovering the data stored in the set of memory cells. In some embodiments, the processing logic can retrieve the offset table 430. In response to retrieving the offset table 430, the processing logic can identify an entry of the offset table 430, where the entry includes an identifier of the bin. In response to identifying the entry including the identifier of the bin, the processing logic can identify the set of threshold voltage offsets assigned to the bin. In response to identifying the set of threshold voltage offsets assigned to the bin, the processing logic can update the threshold voltage offset corresponding to the appropriate threshold voltage level by replacing the threshold voltage offset (e.g., the first threshold voltage offset) with the threshold voltage offset that lead to successfully recovering the data stored in the set of memory cells.

In some embodiments, the processing logic can perform a modification to the first threshold voltage offset assigned to the bin. Performing the modification can include using a predefined parameter and the first threshold voltage offset. For example, performing the modification can include performing a computation to add the first threshold voltage offset to the threshold voltage offset that lead to successfully recovering the data stored in the set of memory cells. In some embodiments, performing the modification can include applying a parameter, where the parameter is a value, e.g., less than 1, that is predefined to avoid overfitting errors when performing the computation. For example, an example computation to perform the modification can be the following:

$$modified read level offset = ( rd\_offset \_old + α * rd\_offset \_new ) / ( 1 - α ) ,$$

where rd_offset_old is the first threshold voltage offset assigned to the bin, rd_offset_new is the new threshold voltage offset (e.g., the threshold voltage offset that lead to successfully recovering the data stored in the set of memory cells), and a is the predefined parameter. In some embodiments, a can be a value that is less than 1.

In response to performing the modification to the first threshold voltage offset, the processing logic can update the identified entry of the data structure by assigning the modified threshold voltage offset to the bin. For example, the processing logic can replace the assigned first threshold voltage offset with the modified threshold voltage offset.

In some embodiments, in response to updating the first threshold voltage offset, the processing logic can receive another (e.g., a second) read command on a set of memory cells addressable by the same wordline group as the read command received at operation 501. The processing logic can perform a read operation using the updated threshold voltage offset.

In some embodiments, to update the threshold voltage offset, the processing logic can perform a media scan operation on the set of memory cells addressable by a first wordline of the wordline group. For example, performing the media scan operation can include performing a data integrity check to verify that the data stored on the set of memory cells addressable by the first wordline does not include any errors. During the data integrity check, one or more reliability statistics are determined for data stored on the set of memory cells addressable by the first wordline. One example of a reliability statistic is raw bit error rate (RBER). In some embodiments, in response to performing the media scan operation, the processing logic can identify another (e.g., a second) threshold voltage offset associated with performing the media scan operation. For example, the second threshold voltage offset can be the threshold voltage offset used in obtaining a minimum and/or optimal RBER for data stored on the set of memory cells addressable by the first wordline. In response to identifying the threshold voltage offset, the processing logic can update the threshold voltage offset assigned to the bin with the second threshold voltage offset, as described above

In some embodiments, to update the threshold voltage offset, the processing logic can identify a temperature of the block family. For example, the processing logic can measure the temperature using a temperature sensor associated with the memory device. In response to identifying the temperature of the block family, the processing logic can update an entry of a data structure stored, e.g., on the memory device 130 of FIG. 1A with the identified temperature of the block family. For example, the processing logic can retrieve the block table 410. In response to retrieving the block table 410, the processing logic can identify an entry of the block table 410, where the entry includes an identifier of the bin. In response to identifying the entry including the identifier of the block family, the processing logic can identify the temperature associated with the block family. In response to identifying the temperature associated with the block family, the processing logic can update the associated temperature included in the entry with the identified temperature. For example, the processing logic can replace the associated temperature with the identified temperature.

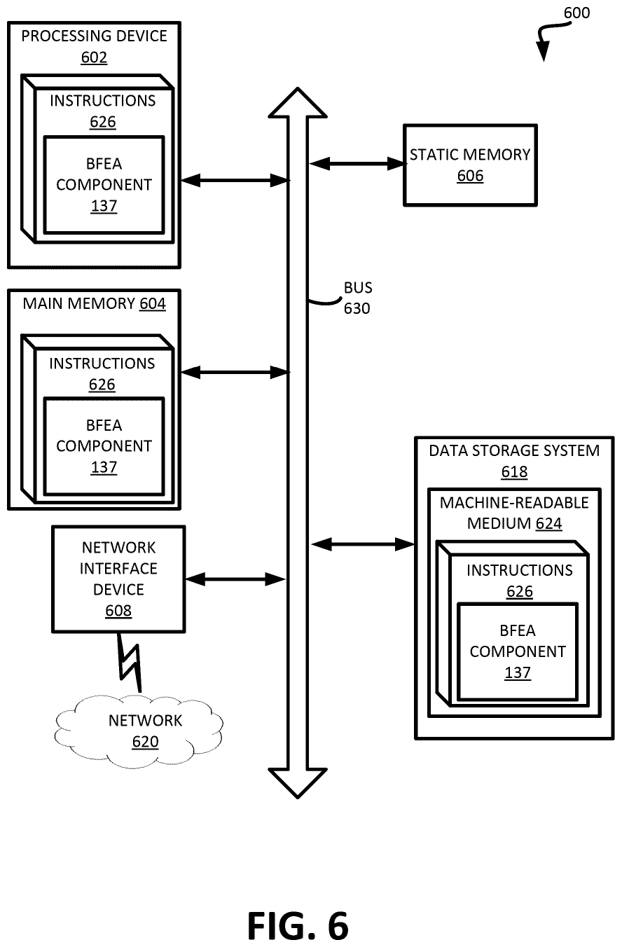

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the BFEA component 137 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a memory cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or RDRAM, etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1A.

In one embodiment, the instructions 626 include instructions to implement functionality corresponding to a BFEA component (e.g., the BFEA component 137 of FIG. 1A). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device: and
a processing device, operatively coupled with the memory device, to perform operations comprising:
receiving a read command specifying a logical address;
translating the logical address into a physical address referencing a physical block stored on the memory device;
identifying a wordline group associated with the physical address;
identifying, based on block family metadata associated with the memory device, a block family associated with the physical block and the wordline group;
determining a first threshold voltage offset associated with the block family; and
reading, using the first threshold voltage offset, data from the physical block.

2. The system of claim 1, wherein determining the first threshold voltage offset associated with the block family further comprises:
identifying, based on the block family metadata associated with the memory device, a first bin of a plurality of bins associated with the block family, wherein each bin of the plurality of bins defines a respective grouping of wordlines based on elapsed time since programming; and
determining, based on the first bin associated with the block family and the wordline group, the first threshold voltage offset.

3. The system of claim 2, wherein the operations further comprise:
detecting a read error in response to performing a read operation on a plurality of memory cells addressable by a wordline of the wordline group associated with the physical address;
performing an error handling operation on the plurality of memory cells addressable by the wordline;
in response to determining that the error handling operation successfully recovered data with respect to the plurality of memory cells addressable by the wordline, identifying a second threshold voltage offset associated with performing the error handling operation; and
updating the first bin with the second threshold voltage offset.

4. The system of claim 3, wherein updating the first bin with the second threshold voltage offset further comprises:
retrieving a data structure comprising a plurality of entries, wherein each entry comprises an identifier of a bin of the plurality of bins and a plurality of threshold voltage offsets assigned to the bin;
identifying, based on the data structure, a first entry comprising an identifier of the first bin and the first threshold voltage offset assigned to the first bin; and
updating the first entry of the data structure by assigning the second threshold voltage offset to the first bin.

5. The system of claim 3, wherein updating the first bin with the second threshold voltage offset further comprises:
retrieving a data structure comprising a plurality of entries, wherein each entry comprises an identifier of a bin of the plurality of bins and a plurality of threshold voltage offsets assigned to the bin;
identifying, based on the data structure, a first entry comprising an identifier of the first bin and a first threshold voltage offset assigned to the first bin;
performing, using a predefined parameter and the first threshold voltage offset, a modification to the second threshold voltage offset; and
updating the first entry of the data structure by assigning the modified threshold voltage offset to the first bin.

6. The memory device of claim 3, wherein the operations further comprise:
performing a media scan operation on a plurality of memory cells addressable by a first wordline of the wordline group;
identifying a threshold voltage offset associated with performing the media scan operation; and
updating the first bin with the second threshold voltage offset.

7. The memory device of claim 1, wherein the operations further comprise:
identifying a temperature of the block family;
retrieving a data structure comprising a plurality of entries, wherein each entry comprises an identifier of a grouping of wordlines of a plurality of groupings of wordlines, an associated block family of a plurality of block families, and an associated temperature; and
updating a first entry of the data structure with the temperature of the block family.

8. A method, comprising:
receiving a read command specifying a logical address;
translating the logical address into a physical address referencing a physical block stored on a memory device;
identifying a wordline group associated with the physical address;
identifying, based on block family metadata associated with the memory device, a block family associated with the physical block and the wordline group;
determining a first threshold voltage offset associated with the block family; and
reading, using the first threshold voltage offset, data from the physical block.

9. The method of claim 8, wherein determining the first threshold voltage offset associated with the block family further comprises:
identifying, based on the block family metadata associated with the memory device, a first bin of a plurality of bins associated with the block family, wherein each bin of the plurality of bins defines a respective grouping of wordlines based on elapsed time since programming; and
determining, based on the first bin associated with the block family and the wordline group, the first threshold voltage offset.

10. The method of claim 9, further comprising:
detecting a read error in response to performing a read operation on a plurality of memory cells addressable by a wordline of the wordline group associated with the physical address;
performing an error handling operation on the plurality of memory cells addressable by the wordline;
in response to determining that the error handling operation successfully recovered data with respect to the plurality of memory cells addressable by the wordline, identifying a second threshold voltage offset associated with performing the error handling operation; and
updating the first bin with the second threshold voltage offset.

11. The method of claim 10, wherein updating the first bin with the second threshold voltage offset further comprises:
retrieving a data structure comprising a plurality of entries, wherein each entry comprises an identifier of a bin of the plurality of bins and a plurality of threshold voltage offsets assigned to the bin;
identifying, based on the data structure, a first entry comprising an identifier of the first bin and the first threshold voltage offset assigned to the first bin; and
updating the first entry of the data structure by assigning the second threshold voltage offset to the first bin.

12. The method of claim 10, wherein updating the first bin with the second threshold voltage offset further comprises:
retrieving a data structure comprising a plurality of entries, wherein each entry comprises an identifier of a bin of the plurality of bins and a plurality of threshold voltage offsets assigned to the bin;
identifying, based on the data structure, a first entry comprising an identifier of the first bin and a first threshold voltage offset assigned to the first bin;
performing, using a predefined parameter and the first threshold voltage offset, a modification to the second threshold voltage offset; and
updating the first entry of the data structure by assigning the modified threshold voltage offset to the first bin.

13. The method of claim 10, further comprising:
performing a media scan operation on a plurality of memory cells addressable by a first wordline of the wordline group;
identifying a threshold voltage offset associated with performing the media scan operation; and
updating the first bin with the second threshold voltage offset.

14. The method of claim 8, further comprising:
identifying a temperature of the block family;
retrieving a data structure comprising a plurality of entries, wherein each entry comprises an identifier of a grouping of wordlines of a plurality of groupings of wordlines, an associated block family of a plurality of block families, and an associated temperature; and
updating a first entry of the data structure with the temperature of the block family.

15. A non-transitory computer-readable storage medium comprising instructions that, when executed by a processing device, cause the processing device to perform operations, comprising:
receiving a read command specifying a logical address;
translating the logical address into a physical address referencing a physical block stored on a memory device;
identifying a wordline group associated with the physical address;
identifying, based on block family metadata associated with the memory device, a block family associated with the physical block and the wordline group;
determining a first threshold voltage offset associated with the block family; and
reading, using the first threshold voltage offset, data from the physical block.

16. The non-transitory computer-readable storage medium of claim 15, wherein determining the first threshold voltage offset associated with the block family further comprises:
identifying, based on the block family metadata associated with the memory device, a first bin of a plurality of bins associated with the block family, wherein each bin of the plurality of bins defines a respective grouping of wordlines based on elapsed time since programming; and
determining, based on the first bin associated with the block family and the wordline group, the first threshold voltage offset.

17. The non-transitory computer-readable storage medium of claim 16, wherein the operations further comprise:
detecting a read error in response to performing a read operation on a plurality of memory cells addressable by a wordline of the wordline group associated with the physical address;
performing an error handling operation on the plurality of memory cells addressable by the wordline;
in response to determining that the error handling operation successfully recovered data with respect to the plurality of memory cells addressable by the wordline, identifying a second threshold voltage offset associated with performing the error handling operation; and
updating the first bin with the second threshold voltage offset.

18. The non-transitory computer-readable storage medium of claim 16, wherein updating the first bin with the second threshold voltage offset further comprises:
retrieving a data structure comprising a plurality of entries, wherein each entry comprises an identifier of a bin of the plurality of bins and a plurality of threshold voltage offsets assigned to the bin;
identifying, based on the data structure, a first entry comprising an identifier of the first bin and the first threshold voltage offset assigned to the first bin; and
updating the first entry of the data structure by assigning the second threshold voltage offset to the first bin.

19. The non-transitory computer-readable storage medium of claim 16, wherein updating the first bin with the second threshold voltage offset further comprises:
retrieving a data structure comprising a plurality of entries, wherein each entry comprises an identifier of a bin of the plurality of bins and a plurality of threshold voltage offsets assigned to the bin;
identifying, based on the data structure, a first entry comprising an identifier of the first bin and a first threshold voltage offset assigned to the first bin;
performing, using a predefined parameter and the first threshold voltage offset, a modification to the second threshold voltage offset; and
updating the first entry of the data structure by assigning the modified threshold voltage offset to the first bin.

20. The non-transitory computer-readable storage medium of claim 15, wherein the operations further comprise:
identifying a temperature of the block family;
retrieving a data structure comprising a plurality of entries, wherein each entry comprises an identifier of a grouping of wordlines of a plurality of groupings of wordlines, an associated block family of a plurality of block families, and an associated temperature; and
updating a first entry of the data structure with the temperature of the block family.
